(19) United States
(12) Patent Application Publication
(10) Pub. No.: US 2025/0137166 A1
(43) Pub. Date: May 1, 2025

(54) GROWTH METHOD AND GROWTH DEVICE FOR SILICON CARBIDE CRYSTAL

(71) Applicant: CEC Compound Semiconductor Co., Ltd, Ningbo (CN)

(72) Inventors: Weiming XUE, Ningbo (CN); Yuan MA, Ningbo (CN); Lei WU, Ningbo (CN); Yaobo PAN, Ningbo (CN)

(73) Assignee: CEC Compound Semiconductor Co., Ltd, Ningbo (CN)

(21) Appl. No.: 18/692,331

(22) PCT Filed: Sep. 16, 2022
(86) PCT No.: PCT/CN2022/119228

§ 371 Date: Mar. 15, 2024

(30) Foreign Application Priority Data
Mar. 29, 2022 (CN) 202210314813.2

(51) Int. Cl. C30B 23/00; C30B 29/36

(52) U.S. Cl. CPC C30B 23/002; C30B 29/36

(57) ABSTRACT

The disclosure provides a growth method and a growth device for silicon carbide crystal. The method at least includes steps of heating a silicon carbide and monitoring a temperature thereof, monitoring a silicon content in the silicon carbide that is evaporated when the silicon carbide is heated to reach a preset temperature, starting to reduce a pressure for nucleation when the silicon content reaches a first preset content value, detecting a radiation of a specific wavelength generated by crystallization at a growth interface when the silicon carbide grows and recording the radiation as a first characteristic radiation, and adjusting the first characteristic radiation to be consistent with a characteristic radiation of a required crystal form when the first characteristic radiation is inconsistent with the characteristic radiation of the required crystal form of the silicon carbide. The disclosure can effectively regulate the selection of crystal forms during the crystal growth process.

### FIELD OF THE INVENTION

The disclosure relates to the technical field of wafer growth, in particular, to a growth method and a growth device for silicon carbide crystal.

### DESCRIPTION OF THE PRIOR ART

Silicon carbide (SiC), as the third generation semiconductor material, has gradually been used in high-power and high-voltage fields. In particular, new energy automobile companies are actively deploying the silicon carbide industry, but the yield rate of silicon carbide crystals/ingots is only about 50%.

The growth method for silicon carbide crystal is Physical Vapor Transport method (PVT). During the growth process, not much information can be obtained under visible light conditions, while infrared dual-color thermometers are often used to detect crystal growth. Since there are many crystal forms of silicon carbide crystals, the infrared thermometer itself has large errors, and the infrared thermometer can only reflect temperature information to determine the crystal growth. This indirect method to understand the raw material atmosphere in the crucible or the growth interface of the crystal requires a lot of experience and has low repeatability, as well as large errors in the final detection results.

### SUMMARY OF THE INVENTION

The disclosure provides a growth method and a growth device for silicon carbide crystal, which may detect the characteristic radiation generated during the phase transition of the crystallization of the silicon carbide to obtain crystallization information of the silicon carbide for judging the growth situation, and meanwhile may intervene the crystallization process, adjust the crystal form of silicon carbide and stabilize the process of the crystal growth.

In order to solve the above technical problem, the disclosure provides the following technical solutions:

The disclosure provides a growth method for silicon carbide crystal, which at least includes steps of:
heating a silicon carbide and monitoring a temperature of the silicon carbide;
monitoring a silicon content in the silicon carbide that is evaporated when the silicon carbide is heated to reach a preset temperature;
starting to reduce a pressure for nucleation when the silicon content reaches a first preset content value;
detecting a radiation of a specific wavelength generated by crystallization at a growth interface when the silicon carbide grows and recording the radiation as a first characteristic radiation; and
adjusting the first characteristic radiation to be consistent with a characteristic radiation of a required crystal form when the first characteristic radiation is inconsistent with the characteristic radiation of the required crystal form of the silicon carbide.

In an embodiment of the disclosure, the first preset content value is 0.5%-45%.

In an embodiment of the disclosure, a range of the specific wavelength is 0.01-100 μm.

In an embodiment of the disclosure, the first characteristic radiation is an electromagnetic wave with a wavelength in a range of a far infrared wavelength, a mid-infrared wavelength, a visible light wavelength, an ultraviolet wavelength and a deep ultraviolet wavelength.

In an embodiment of the disclosure, the step of adjusting the first characteristic radiation to be consistent with a characteristic radiation of a required crystal form includes steps of:
determining a range of a radiation wavelength in which a first characteristic radiation peak is located according to the detected first characteristic radiation;
obtaining an energy change value generated at the crystallization interface during a crystal growth process according to the range of the radiation wavelength;
changing a total energy of the silicon carbide crystal at the crystallization interface or an uncrystallized vapor silicon carbide during the crystal growth process according to energy changes generated at the crystallization interface during the crystal growth process so that the first characteristic radiation generated during the crystal growth process is consistent with the characteristic radiation of the required crystal form.

In an embodiment of the disclosure, the energy change value generated at the crystallization interface during the crystal growth process is obtained by a formula of:

En=hcNA/(λn);
wherein h is Planck's constant, c is the speed of light, NA is Avogadro constant, and λn is the radiation wavelength.

In an embodiment of the disclosure, the step of adjusting the first characteristic radiation to be consistent with a characteristic radiation of a required crystal form includes a step of applying an additional radiation to the silicon carbide crystal at the crystallization interface or the uncrystallized vapor silicon carbide.

In an embodiment of the disclosure, the additional radiation is an additional electromagnetic wave or an additional infrared laser.

In an embodiment of the disclosure, the growth method for silicon carbide further includes, after applying an additional radiation to the silicon carbide crystal at the crystallization interface or the uncrystallized vapor silicon carbide, a step of increasing the pressure and lowering the temperature to room temperature when the silicon content is lower than a second preset content value.

The disclosure further provides a growth device for silicon carbide crystal, which is used for executing the growth method for silicon carbide crystal and at least includes:
a crucible, used to hold the silicon carbide;
a heating body, used to heat the crucible filled with the silicon carbide;
crucible bottom observation holes, provided at a bottom of the crucible; and
crucible side wall observation holes, provided along a circumference of a side wall of the crucible and located at the crystallization interface.

The disclosure provides a growth method and a growth device for silicon carbide crystal, which detects the characteristic radiation generated during the phase transition of the crystallization of the silicon carbide to obtain crystallization information of the silicon carbide for judging the growth situation, and meanwhile intervenes the crystallization process, optimizes the crystal form of the silicon carbide and effectively improves the crystal quality.

### BRIEF DESCRIPTION OF THE DRAWINGS

FIG. 1 is a flowchart according to the disclosure.

FIG. 2 is a diagram of a growth device according to the disclosure.

FIG. 3 is diagram of a characteristic radiation of an infrared light according to an embodiment of the disclosure.

FIG. 4 is diagram of the characteristic radiation of the infrared light according to Comparative Example 2 of the disclosure.

### DESCRIPTION OF REFERENCE NUMERALS

100-silicon carbide crystal; 200-crucible; 210-crucible side wall observation hole; 220-crucible bottom observation hole; 300-silicon carbide material source; 400-heating body.

### DESCRIPTION OF THE PREFERRED EMBODIMENTS

Through specific examples of the disclosure below, technicians of the field can easily understand other advantages and efficiencies of the disclosure revealed by the specification The disclosure can also be implemented or applied through other different ways, and the details of the specification can also be modified or changed based on different views and applications without deviating from the disclosure.

It should be noted that, the diagrams provided in the following embodiments only illustrate the basic conceptions of the disclosure in a schematic way, thus only components relative to the disclosure are shown instead of drawing the number of components, shape and size in actual implementation, in which the type, number and proportion of each group can be a kind of random change, and its component, layout type may also be more complex.

The technical solution of the disclosure will be further described in detail below with reference to several embodiments and drawings. Obviously, the described embodiments are only some of the embodiments of the disclosure, rather than all of the embodiments. Based on the embodiments of the disclosure, all other embodiments obtained by a person skilled in the art without involving any inventive effort are within the scope of the disclosure.

Silicon carbide is a wide bandgap semiconductor material. Since silicon carbide has incomparable excellent properties, such as high thermal conductivity, high saturation electron mobility and high breakdown electric field strength, it is used in the preparation of various semiconductor devices. Silicon carbide semiconductor devices mainly include power diodes and power transistors. Silicon carbide semiconductor devices have the characteristics of high frequency, high efficiency, and high temperature, and may be used in fields with strict efficiency or temperature requirements, e.g., solar inverters, vehicle power supplies, new energy vehicle motor controllers, UPS, charging piles, power supplies and other fields.

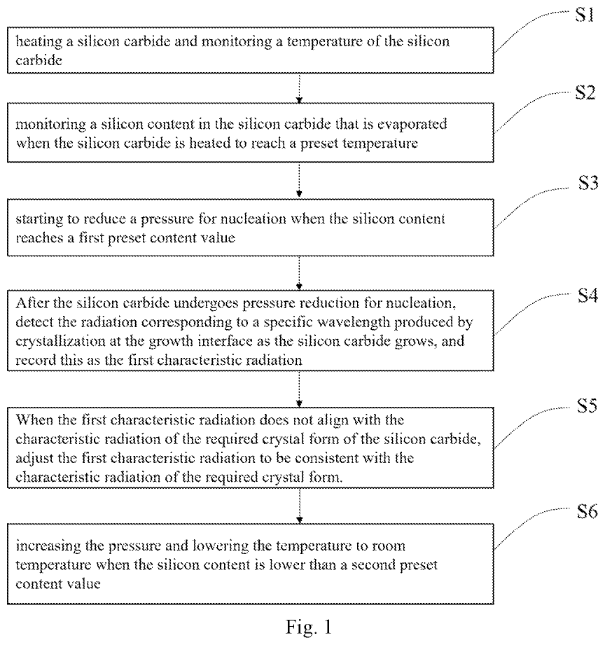

With reference to FIG. 1, the disclosure provides a growth method for silicon carbide crystal, which includes but is not limited to the following steps S1-S6.
S1, a silicon carbide is heated and a temperature of the silicon carbide is monitored.
S2, a silicon content in an evaporated silicon carbide is monitored when a temperature of the silicon carbide is increased to a preset temperature.
S3, a pressure is started to be reduced for nucleation when the silicon content reaches a first preset content value.
S4, after the silicon carbide is reduced in pressure for nucleation, a radiation corresponding to a specific wavelength generated by crystallization at an interface is detected when the silicon carbide grows and the radiation is recorded as a first characteristic radiation.
S5, the first characteristic radiation is adjusted to be consistent with a characteristic radiation of a required crystal form when the first characteristic radiation is inconsistent with the characteristic radiation of the required crystal form of the silicon carbide.
S6, the pressure is increased and the temperature is lowered to room temperature when the silicon content is lower than a second preset content value.

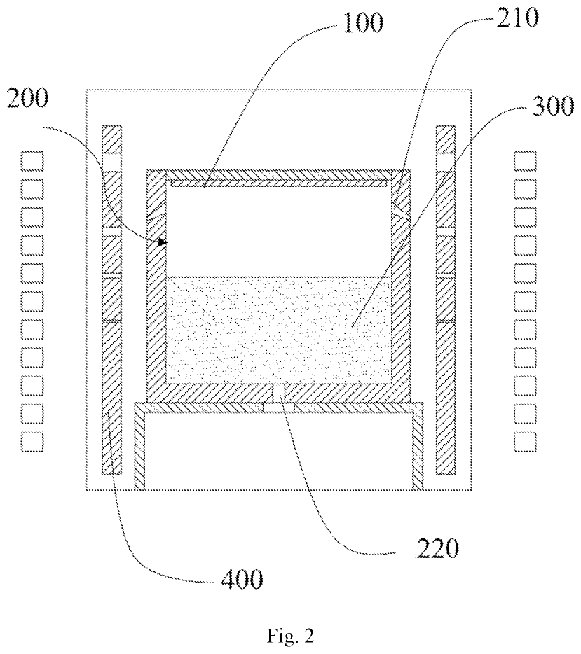

With reference to FIGS. 1 to 2, in an embodiment of the disclosure, in the step S1, a silicon carbide material source 300 may be placed in a high-temperature-resistant container, and then placed in a thermal field to be heated by a heating body 400. The application does not impose restrictions on the container holding the silicon carbide material source 300. In an embodiment of the disclosure, the container may be, for example, a crucible, and further may be, for example an isostatic graphite crucible, or may be, for example, a tantalum carbide crucible in other embodiments. In an embodiment of the disclosure, for example, a plurality of observation holes may be provided on the crucible 200 to monitor the temperature of the silicon carbide and the content of evaporated silicon carbide in the thermal field. In an embodiment of the disclosure, for example, at least one bottom observation hole 220 may be provided at a bottom of the crucible 200, and a diameter of the bottom observation hole 220 may be set to 1-5 mm, for example. In an embodiment of the disclosure, for example, a plurality of side wall observation holes 210 may be provided on a side wall of the crucible; the side wall observation holes 210 may be, for example, provided close to the crystallization interface and evenly distributed along a circumference of the side wall of the crucible; a diameter of the side wall observation hole 210 may be, for example, set to 1-5 mm.

With reference to FIGS. 1 to 2, in an embodiment of the disclosure, a heating program of the thermal field may be configured to control the pressure and the temperature of the growth process of the silicon carbide. In an embodiment of the disclosure, the thermal field is, for example, a single crystal growth furnace. In the step S1, before the silicon carbide is heated, the pressure of the growth process of the silicon carbide is further configured. The thermal field with constant system pressure may maintain the stability of the vapor components and the thermal field in the growth system, allowing the growth of the silicon carbide crystal to proceed in a near-equilibrium state. When the pressure of the growth is reduced, the growth rate increases significantly. When the pressure is reduced to 100 Pa, the growth rate approaches saturation. In an embodiment of the disclosure, the pressure of the growth in the thermal field may be configured to, for example, 100 mbar-900 mbar; furthermore, optionally, the pressure of the growth may be configured to, for example, 100 mbar; the pressure of the growth may also be configured to, for example, 500 mbar, and the pressure of the growth may also be configured to, for example, 900 mbar.

With reference to FIGS. 1 to 2, in an embodiment of the disclosure, the growth rate of the silicon carbide crystal increases with temperature, but the silicon carbide will decompose when the temperature reaches 2830° C. and above. In the step S2, the preset temperature during the growth of the silicon carbide may be configured in a range of 2000° C. to 2500° C., for example. Further, the preset temperature may be configured to, for example, 2000° C., the preset temperature may also be configured to, for example, 2200° C., and the preset temperature may be also configured, for example, 2500° C. In an embodiment of the disclosure, the silicon carbide material source 300 may be heated by the heating body 400; when a temperature of the silicon carbide material source 300 rises to the preset temperature, the silicon carbide material source is partially evaporated. In an embodiment of the disclosure, for example, the silicon content in the evaporated silicon carbide may be detected through the crucible bottom observation holes 220. In an embodiment of the disclosure, for example, gas chromatography mass spectrometry may be used to detect the silicon content in the silicon carbide evaporated in a thermal field; in other embodiments, for example, gas chromatography may also be used to detect the silicon content in the silicon carbide evaporated in the thermal field.

With reference to FIGS. 1 to 2, in an embodiment of the disclosure, after the preset temperature is reached, the silicon content in the thermal field gradually increases. The silicon content in the thermal field needs to be monitored in real time before performing the step S3. When the silicon content reaches the first preset content value, the pressure is started to be reduced for nucleation and crystallization of the silicon carbide evaporated in the thermal field. In an embodiment of the disclosure, the first preset content value may be configured in a range of 0.5%-45%, for example; furthermore, optionally, the first preset content value may be, for example, 0.5%, and the first preset content value may also be, for example, 25%; the first preset content value may also be, for example, 45%. In an embodiment of the disclosure, for example, the pressure for the growth of the silicon carbide may be adjusted by adjusting a flow rate of a protective atmosphere in the thermal field. In an embodiment of the disclosure, the protective atmosphere may be, for example, argon gas, and the flow rate of the protective atmosphere may be configured in a range of 1 to 1000 sccm, for example.

With reference to FIGS. 1 to 2, in the step S4, when the silicon carbide grows, the crystallization at various growth interfaces causes phase transitions, generating the characteristic radiation within a specific wavelength range, which is recorded as the first characteristic radiation, thereby determining the radiation wavelength range where the first characteristic radiation peak is located. The radiation wavelength corresponding to the characteristic radiation peak of 4H silicon carbide is in a range of 0.54 μm-5.5 μm, and the differences in atomic arrangement of the many crystal forms of the silicon carbide (6H, 3C or 15R, etc.) lead to differences in bond energy; therefore, the radiation wavelengths corresponding to the characteristic radiation peaks of the silicon carbides with different crystal forms have their own ranges. By detecting the radiation of the specific wavelength, the radiation wavelength range may be determined through the characteristic radiation peak, thereby determining the actual growth crystal form of the silicon carbide.

In an embodiment of the disclosure, the specific wavelength may be in a range of 0.01 μm to 100 μm, for example. In the step S4, the first characteristic radiation may be detected through the crucible sidewall observation hole 210. In an embodiment of the disclosure, the first characteristic radiation may be, for example, electromagnetic waves generated at wavelengths in far infrared, mid-infrared, visible light, ultraviolet, deep ultraviolet and other wavelength bands. In an embodiment of the disclosure, for example, an optical fiber may be used to transmit a radiation signal from the crucible side wall observation hole 210 to a detection device to detect the first characteristic radiation to avoid signal loss. The optical fiber needs to have good transmittance to infrared light, and the material of the optical fiber is not limited. In an embodiment of the disclosure, for example, Al₂O₃ optical fiber may be used. In other embodiments, for example, CaF optical fiber may also be used.

With reference to FIGS. 1 to 2, in the step S5, when it is detected that the first characteristic radiation is inconsistent with the characteristic radiation of the required crystal form of the silicon carbide, an additional radiation needs to be applied to adjust the first characteristic radiation to be consistent with the characteristic radiation of the desired crystal form of the silicon carbide. Specifically, a process of the adjustment includes: a range of a radiation wavelength in which a first characteristic radiation peak value is located is determined according to the first characteristic radiation detected in the step S4; an energy change value generated at the crystallization interface is obtained during a crystal growth process according to the range of the radiation wavelength; a total energy of the silicon carbide crystal at the crystallization interface or an uncrystallized vapor silicon carbide is changed during the crystal growth process according to energy changes generated at the crystallization interface during the crystal growth process so that the first characteristic radiation generated during the crystal growth process is consistent with the characteristic radiation of the required crystal form.

In an embodiment of the disclosure, the energy change generated by at the crystallization interface of the silicon carbide may be obtained by the following formula:
Eₙ=hcN_{A}/(λₙ);
wherein h is Planck's constant, c is the speed of light, and NA is Avogadro constant. λn is the radiation wavelength. In the disclosure, a value range of λn is 0.01-100 μm, and En is the radiation energy of 1 mol photon at different wavelengths; in other words, when the silicon carbide crystal grows, according to the detected first characteristic radiation, the radiation wavelength λn corresponding to the peak may be determined, and the energy changes generated at the crystallization interface are inferred based on this formula. Different wavelength bands mean the radiation energy of 1 mol photon is also different.

The reaction formulas [1] and [2] of the decomposition for raw materials and the crystal growth of the silicon carbide during the growth process are as follows:

$$2 SiC ⇔ {SiC}_{2 ( g )} + {Si}_{( lg )} ; \qquad [ 1 ]$$

$$2 SiC ⇔ {Si}_{2} {C}_{( g )} + C . \qquad [ 2 ]$$

The vapor silicon carbide generated near the crystallization interface releases phase transition heat, which is the vaporization enthalpy; the vapor silicon carbide is deposited on the growth interface, and the silicon carbide crystal grows, as shown in reaction formula [3]:

$$SiC ⇔ {SiC}_{( g )} . \qquad [ 3 ]$$

During the reaction, the energy change process follows the formula [4]

$$Δ H = ( Δ {E}_{e} + Δ {E}_{th} ) pre - ( Δ {E}_{e} + Δ {E}_{th} ) rec - nRT . \qquad [ 4 ]$$

In the formula [4], ΔEe represents the vapor electron energy in the crucible, ΔEth represents the thermodynamic energy, (ΔEe+ΔEth) pre represents the total energy of uncrystallized vapor silicon carbide before growth, (ΔEe+ΔEth) rec represents the total energy of the silicon carbide crystal after growing for a period of time, nRT represents the energy change caused by the reduction of n moles of phase molecules due to growth, and ΔH is the enthalpy change. According to the ‘phase transition luminescence’ mechanism, part of the energy is released by the characteristic radiation, and part of the energy is released along the temperature gradient. The characteristic radiation is partially different from the temperature reflected by Planck radiation and contains crystallization information. In addition, due to the chemical reactions of [1] and [2], the change in enthalpy in the system is also affected, and the energy may be removed from ΔH by looking up the table; the enthalpy change energy of Si—C is 318 KJ/mol, the enthalpy change energy of Si—Si is 222 KJ/mol, and the enthalpy change energy of C—C is 306 KJ/mol. ΔH after excluding the bond energy change value during the crystal growth process is consistent with the energy change value En generated at the crystallization interface.

On the other hand, changes in temperature or power during the crystal growth process are actually changes in the thermodynamic energy in the thermal field, i.e., changes in Eth affect the lattice structure of the crystal, thereby changing the crystal quality. However, any energy field that can affect the movement of the crystal lattice may change the crystal structure, while the basic unit of lattice interaction is phonons, i.e., changes in the phonon field in the thermal field may interfere with the crystal lattice structure and change the crystal quality. The phonon field may be that Ee changes electronic energy through electromagnetic waves, or may be that mechanical waves such as vibration change the thermodynamic energy Eth. Such influence may be caused by infrared electromagnetic waves (affecting Eth) or ultraviolet waves (affecting Ee) that can be absorbed by crystal atoms, or ultrasonic waves of mechanical vibration (affecting Eth). Therefore, Eth or Ee may be changed by applying additional radiations, thereby adjusting the range of the characteristic radiation during the growth of the silicon carbide to be consistent with the range of the characteristic radiation of 4H silicon carbide.

TABLE 1
Vapor Pressure of Each Component During Growth
of Silicon Carbide at Different Temperatures

| Temperature (° C.)/ | | | |
|---|---|---|---|
| Evaporation pressure (Pa) | P_{Si}^{sat} (Pa) | P_{SiC}_{₂} | P_{Si}_{₂}_{C} |
| 2300 | 34.72 | 3.84 | 1.97 |
| 2400 | 84.28 | 15.47 | 7.91 |
| 2500 | 190.29 | 55.56 | 28.32 |

From Table 1, it can seen that as the silicon content in the atmosphere in the thermal field changes with the temperature, the proportion of silicon is also constantly changing, and by measuring the content value, it is easy to obtain the reaction conditions of [1] and [2] and determine the appropriate timing to start and end the growth of the silicon carbide crystal.

With reference to FIGS. 1 to 2, the disclosure places no limitations on the type of additional radiation applied; in an embodiment of the disclosure, the additional radiation applied may be, for example, electromagnetic waves; in other embodiments, the additional radiation may also be, for example, an infrared laser. In an embodiment of the disclosure, the applied electromagnetic wave is an alternating current electromagnetic field that can generate eddy currents at the growth interface; a frequency of the applied electromagnetic wave may be in a range of 1-10 kHz, for example, and a power may be in a range of 1 mw-500 mw, for example. In another embodiment of the disclosure, a wavelength of the applied infrared laser may be in a range of 0.1 μm-100 μm, for example, and a power may be in a range of 1 mW-500 mW, for example.

With reference to FIGS. 1 to 2, in the step S6, when the silicon content is lower than the second preset content value after the first characteristic radiation is adjusted to be consistent with the characteristic radiation of the required crystal form of the silicon carbide, the pressure in the thermal field is increased, the temperature is lowered to room temperature, and the process state is maintained to stabilize the growth of the silicon carbide crystal. In an embodiment of the disclosure, the second preset content value may be configured to 0.1%-35%, for example; furthermore, optionally, the second preset content value may be configured to 0.1%, for example; the second preset content value may also be configured to 20%, for example, and the second preset content degree value may also be configured to 35%, for example.

Hereinafter, the disclosure will be explained more specifically by referring to embodiments, which should not be construed as limiting. Appropriate modifications may be made within the scope consistent with the gist of the disclosure, and they all fall within the technical scope of the disclosure.

### Embodiment 1

(1) A crucible containing a silicon carbide material source into a thermal field, as shown in FIG. 2, and the crucible is evacuated to make a pressure of the thermal field less than 1e-5 mbar, followed by filling with Ar until the pressure reaches 600 mbar and heating to 2350° C. at 200° C./h.
(2) An atmosphere in the thermal field is obtained from the crucible bottom observation holes; when the silicon content is detected to reach 12.5% using gas chromatography mass spectrometry/chromatography, a decomposition product of the raw materials in the crucible is mainly Si2C; then, 5 hours are spent to reduce the pressure in the thermal field from 600 mbar to 15 mbar, and the temperature is kept unchanged during the pressure reduction.
(3) After the growth is performed at a constant temperature for 5 hours while stabilizing the pressure at 15 mbar, an infrared radiation value of the vapor silicon carbide is measured in the crucible at 1 μm-5 μm from the crucible side wall observation holes, and the infrared radiation value at the crystallization interface detected in step (2) is recorded.

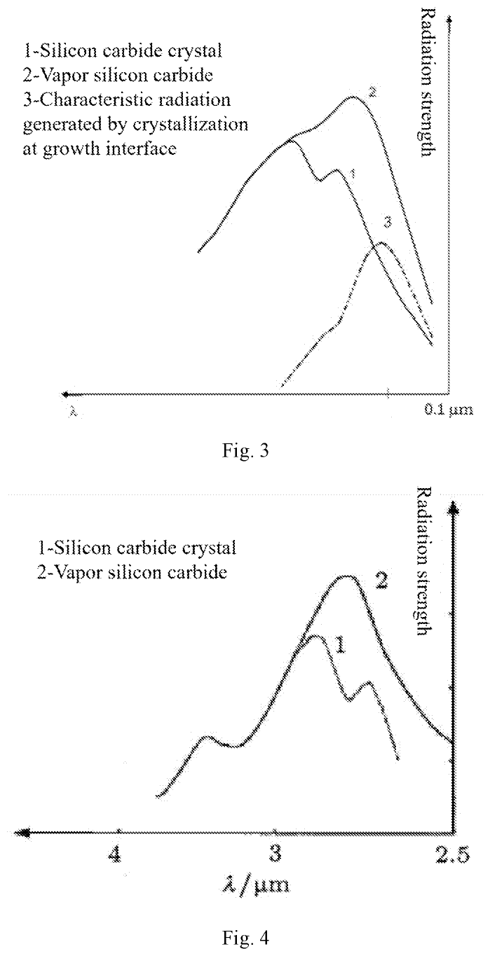

With reference to FIG. 3, Curve 1 is the radiation curve of the silicon carbide crystal, Curve 2 is the radiation curve of uncrystallized vapor silicon carbide, Curve 3 is the radiation curve generated by crystallization at the growth interface, and the radiation value in Curve 3 is a difference between the radiation value of uncrystallized vapor silicon carbide and the radiation value of the silicon carbide crystal. From FIG. 3, it can be seen that there is a characteristic radiation peak in Curve 3, and the characteristic radiation peak is around 0.1-1.5 μm, which is consistent with the enthalpy change for the Si—C bond energy, and is a complete 4H crystal form with low defects; through the crucible side wall observation holes, the radiation values of the entire crystallization interface are recorded to form multiple characteristic peaks, all around 0.1-1.5 μm, and the growth is continued steadily.
(4) When the Si content in the thermal field is less than 2.5%, Ar is filled in to increase the pressure in the thermal field to 300 mbar.
(5) The power is reduced to 0 for 10 hours, the temperature is cooled to room temperature naturally, and the thermal field is opened to take out the crystal.

After inspection, the crystal grown under this condition has BPD less than 1000, TSD less than 100, and has no defects such as phase transition.

### Comparative Example 1

(1) A crucible containing a silicon carbide material source into a thermal field, and the crucible is evacuated to make a pressure of the thermal field less than 1e-5 mbar, followed by filling with Ar until the pressure reaches 600 mbar and heating to 2150° C. at 200° C./h.
(2) 5 hours are spent to reduce the pressure in the thermal field from 600 mbar to 8 mbar, and the temperature is kept unchanged during the pressure reduction.
(3) After the pressure is stabilized at 15 mbar, the growth is performed at a constant temperature for 150 hours.
(4) Ar is filled in to increase the pressure in the thermal field to 300 mbar.
(5) The power is reduced to 0 for 10 hours, the temperature is cooled to room temperature naturally, and the thermal field is opened to take out the crystal.

Since the initial conditions for crystal growth are only pressure and temperature, how the growth process develops is completely unknown; in the early stages of crystal growth, a phase transition occurs near a small area, and then the phase transition continues to expand, wherein the utilization rate of the crystal is almost 0.

### Comparative Example 2

(1) A crucible containing a silicon carbide material source into a thermal field, and the crucible is evacuated to make a pressure of the thermal field less than 1e-5 mbar, followed by filling with Ar until the pressure reaches 600 mbar and heating to 2150° C. at 200° C./h.
(2) An atmosphere in the thermal field is obtained from the crucible bottom observation holes; when the silicon content is obtained to reach 15% using gas chromatography mass spectrometry/chromatography, which is not suitable for the growth of the crystal; then the temperature is continued to be raised to 2280° C., the Si content reaches 13% after another measurement; 5 hours are spent to reduce the pressure in the thermal field from 600 mbar to 10 mbar, and the temperature is kept unchanged during the pressure reduction.
(3) After the growth is performed at a constant temperature for 5 hours while stabilizing the pressure at 15 mbar, an infrared radiation value of the vapor silicon carbide in the crucible at 1 μm-5 μm is obtained by using the Al₂O₃ optical fiber with a diameter of 0.5 mm at an edge of the crucible side wall observation hole, and an angle of the optical fiber is adjusted to measure the infrared radiation value at the crystallization interface; then, recording and comparison are performed.

With reference to FIG. 4, the characteristic radiation peak occurs after 2.5 μm; then, there are other crystal forms on the growth interface, which may be other crystal forms such as 15R or 6H.
(4) The crucible side wall observation holes are used to irradiate the growth interface with a laser with a wavelength of 4.2 μm and a power of 200 mW, while the growth interface is irradiated with an alternating-frequency electric field of 2 KHz and 150 mw while keeping other process parameters, and then the growth is performed stably for 5 hours.
(5) Comparing the radiation value of the vapor silicon carbide and the infrared radiation value of the silicon carbide at the growth interface, the characteristic peak returns to around 1.3 μm, and the growth may be continued then.
(6) The process conditions are maintained for stable growth for 20 h, and the growth of the crystals is detected repeatedly every 20 hours.
(7) When the Si content in the thermal field is less than 1.5%, Ar is filled in to increase the pressure in the thermal field to 200 mbar.
(8) The power is reduced to 0 for 10 hours, the temperature is cooled to room temperature naturally, and the thermal field is opened to take out the crystal.

The obtained crystal is detected using X-rays, and it is found that there was a small phase transition area in the crystal; the recombination energy at the defect is changed to terminate the derivation of the phase transition of the crystal and convert the same into acceptable defects, so that the final utilization rate of the crystal is increased to more than 70%.

In summary, the disclosure provides a growth method and a growth device for silicon carbide crystal, which detects the characteristic radiation generated during the phase transition of the crystallization of the silicon carbide to obtain crystallization information of the silicon carbide for judging the growth situation in real time, and meanwhile intervenes the crystallization process, regulates and optimizes the crystal form of the silicon carbide and effectively improves the crystal quality. The method proposed by the disclosure is also a new method for detecting the crystal form of the silicon carbide and has important application value.

The above description is only a preferred embodiment of the disclosure and an explanation of the technical principles used. Those skilled in the art should understand that the scope of the disclosure involved in the disclosure is not limited to technical solutions formed by specific combinations of the above-mentioned technical features, and should encompass other technical solutions formed by any combination of the above technical features or their equivalent features, e.g., technical solutions formed by replacing the above features with technical features disclosed (but not limited to) in the disclosure with similar functions, without departing from the concept of the disclosure.

Except for the technical features described in the description, the remaining technical features are known to those skilled in the art. In order to highlight the innovative features of the disclosure, the remaining technical features will not be described in detail here.

What is claimed is:

1. A growth method for silicon carbide crystal, at least comprising steps of:
heating a silicon carbide and monitoring a temperature of the silicon carbide;
monitoring a silicon content in the silicon carbide that is evaporated when the silicon carbide is heated to reach a preset temperature;
starting to reduce a pressure for nucleation when the silicon content reaches a first preset content value;
detecting a radiation of a specific wavelength generated by crystallization at a growth interface when the silicon carbide grows and recording the radiation as a first characteristic radiation; and
adjusting the first characteristic radiation to be consistent with a characteristic radiation of a required crystal form when the first characteristic radiation is inconsistent with the characteristic radiation of the required crystal form of the silicon carbide;
wherein the first preset content value is a range of 0.5%-45%, and a range of the specific wavelength is 0.01-100 μm.

2. The growth method for silicon carbide crystal according to claim 1, wherein the step of adjusting the first characteristic radiation to be consistent with a characteristic radiation of a required crystal form comprises steps of:
determining a range of a radiation wavelength in which a first characteristic radiation peak is located according to the detected first characteristic radiation;
obtaining an energy change value generated at the crystallization interface during a crystal growth process according to the range of the radiation wavelength;
changing a total energy of the silicon carbide crystal at the crystallization interface or an uncrystallized vapor silicon carbide during the crystal growth process according to energy changes generated at the crystallization interface during the crystal growth process so that the first characteristic radiation generated during the crystal growth process is consistent with the characteristic radiation of the required crystal form.

3. The growth method for silicon carbide crystal according to claim 2, wherein the energy change value generated at the crystallization interface during the crystal growth process is obtained by a formula of:
En=hcNA/(λn);
wherein h is Planck's constant, c is the speed of light, NA is Avogadro constant, and λn is the radiation wavelength.

4. The growth method for silicon carbide crystal according to claim 1, wherein the step of adjusting the first characteristic radiation to be consistent with a characteristic radiation of a required crystal form further comprises a step of applying an additional radiation to the silicon carbide crystal at the crystallization interface or an uncrystallized vapor silicon carbide.

5. The growth method for silicon carbide crystal according to claim 4, wherein the additional radiation is an additional electromagnetic wave or an additional infrared laser.

6. The growth method for silicon carbide crystal according to claim 4, further comprising, after applying an additional radiation to the silicon carbide crystal at the crystallization interface or the uncrystallized vapor silicon carbide, a step of increasing the pressure and lowering the temperature to room temperature when the silicon content is lower than a second preset content value, wherein the second preset content value is 0.1%-35%.
